(19) United States
(12) Patent Application Publication
(10) Pub. No.: US 2024/0204140 A1
(43) Pub. Date: Jun. 20, 2024

(54) MICRO LIGHT-EMITTING DIODE AND DISPLAY DEVICE USING THE SAME

(71) Applicant: XIAMEN SAN’AN OPTOELECTRONICS CO., LTD., Xiamen, Fujian (CN)

(72) Inventors: Kechuang LIN, Xiamen (CN); Zheng WU, Xiamen (CN); Zhiyuan WANG, Xiamen (CN); Zhilei QIN, Xiamen (CN); Chia-En LEE, Xiamen (CN)

(21) Appl. No.: 18/541,350

(22) Filed: Dec. 15, 2023

(30) Foreign Application Priority Data
Dec. 16, 2022 (CN) 202211682812.X
Dec. 27, 2022 (CN) 202211682816.8
Nov. 29, 2023 (CN) 202311433446.9

(51) Int. Cl. H01L 33/38; H01L 25/075; H01L 33/20; H01L 33/40; H01L 33/46

(52) U.S. Cl. CPC H01L 33/382; H01L 25/0753; H01L 33/20; H01L 33/40; H01L 33/46

(57) ABSTRACT

A micro LED includes a semiconductor layered structure, a first metallic electrode, a second metallic electrode, and an insulating layered unit. The semiconductor layered structure has a first mesa, and a second mesa. A portion of the insulating layered unit on the first mesa has a first insulating layer. A portion of the insulating layered unit on the second mesa has a second insulating layer. The first insulating layer has a first opening. The second insulating layer includes a first sublayer that covers the second mesa and has a second opening, and a second sublayer covering the first sublayer and formed with a third opening. A projection of the second opening falls within a projection of the third opening. The second metallic electrode extends from the second opening to the third opening. At least one of the first and second sublayers is exposed within the third opening.

### CROSS-REFERENCE TO RELATED APPLICATION

This application claims priority to Chinese Invention Patent Application No. 202211682812.X, filed on Dec. 16, 2022, Chinese Invention Patent Application No. 202211682816.8, filed on Dec. 27, 2022, and Chinese Invention Patent Application No. 202311433446.9 filed on Nov. 29, 2023, all three of which are incorporated by reference herein in their entirety.

### FIELD

The disclosure relates to a semiconductor and a display, and more particularly to a light-emitting diode and a display device using the same.

### BACKGROUND

Micro light-emitting diodes (LEDs) are highly anticipated to be the next generation of display technology and have become a hot topic of research. micro LEDs have advantages such as high energy efficiency, high brightness, ultra high resolution and high color saturation, fast response speed, low energy consumption, and long operating lifetime. Additionally, the energy consumption of micro LEDs is approximately only 10% of liquid crystal displays (LCDs), and 50% of organic light-emitting diodes (OLED)s. Additionally, although micro LED displays are similar to OLED displays in that they emit their own light and do not require a backlight, micro LED displays can emit much brighter light, and reach much higher pixel densities. These advantages make micro LED displays a good candidate to replace OLED displays and LCD displays as the display technology for the next generation. However, mass production of micro LEDs is currently not possible due to various technical challenges that need to be overcome. One such technical challenge is to increase micro LED chip yield rates during fabrication.

During the fabrication of micro LEDs, for example when fabricating micro LED chips for a high pixel density micro LED display, a process of transfer printing is performed. Referring to FIG. 1, a micro LED 1 fabricated during this process will have dimensions that range from 100 μm to 150 μm. The transfer printing process involves steps of stamping, pick up and deposition of ultra thin (or ultra miniature) devices. Micro transfer printing is a mass transfer technique that allows selective array assembly and collection of microscopic high performance devices onto a non-native substrate. In the simplest analogy, micro transfer printing is similar to a stamp transferring ink fluid from an ink station to a piece of paper. However, in the case of micro transfer printing the “ink” is composed of high performance solid state semiconductor devices, and the “paper” may be PCB circuit boards, plastic films, or semiconductor substrates. Micro transfer printing technology utilizes an elastic stamp device 2 to couple with a high precision movement controlled printhead to selectively pick up arrays of microscopic devices and transfer print them on a non-native substrate.

Referring to FIG. 2 during the mass transfer process, the elastic stamp device 2 pressurizes and stamps a plurality of micro LEDs 1. For each micro LED 1, there is a depression (G) on a side of the micro LED 1 distal to the elastic stamp device 2. For example, in FIG. 2, the micro LED 1 has a depression (G) on an N-type window layer of a semiconductor layered structure. When the micro LED 1 undergoes the mass transfer process, fractures (C) may form at an interface of a first mesa (M) and a mesa side wall (S). This is especially likely to occur if the micro LED 1 was planarized, roughened or patterned via etching on another side of the micro LED 1 that is proximate to the elastic stamp device.

### SUMMARY

Therefore, an object of the disclosure is to provide a micro light-emitting diode (LED) and a display device that can alleviate at least one of the drawbacks of the prior art.

According a first aspect of the disclosure, the micro light-emitting diode (LED) includes a semiconductor layered structure, a first metallic electrode, a second metallic electrode, and an insulating layered unit. The semiconductor layered structure includes a front side and a back side. The semiconductor layered structure further includes a first-type semiconductor layer, an active layer, and a second-type semiconductor layer sequentially disposed in a thickness direction from the front side to the back side of the semiconductor structure. The semiconductor layered structure has a first depression, a first mesa, a second mesa, and a mesa side wall. The first depression is on the back side and indents in the thickness direction from the second-type semiconductor layer to the first-type semiconductor layer through the active layer to partially expose the first-type semiconductor layer. The first mesa is formed at the first-type semiconductor layer. The second mesa is formed on the second-type semiconductor layer. The mesa side wall is located between the first mesa and the second mesa. The first metallic electrode is disposed on the back side of the semiconductor layered structure, and electrically connected to the first-type semiconductor structure. The second metallic electrode is disposed on the back side of the semiconductor layered structure, and electrically connected to the second type semiconductor structure. The insulating layered unit is disposed on and covering the semiconductor layered structure and extends from the first mesa to the second mesa. A portion of the insulating layered unit on the first mesa has a first insulating layer disposed on the first mesa. A portion of the insulating layered unit on the second mesa has a second insulating layer. The second insulating layer has a first sublayer covering the second mesa, and a second sublayer covering the first sublayer. The first insulating layer has a first opening formed on the first mesa. The first metallic electrode extends from inside of the first opening on the first mesa to an outside surface of the first insulating layer. The first sublayer of the second insulating layer has a second opening formed on the second mesa. The second metallic electrode is partially disposed in the second opening. A third opening is formed above the second opening and disposed in the second sublayer of the second insulating layer. A perpendicular projection of the second opening onto a plane parallel to the back side of the semiconductor layered structure entirely falls within a perpendicular projection of the third opening onto the plane. The second metallic electrode extends from inside of the second opening to the third opening, and a boundary wall of the second insulating layer that is exposed within the third opening includes at least one of the first sublayer and the second sublayer.

According to another aspect of the disclosure, the display device includes a printed circuit board (PCB) board, and includes the micro LED in the first aspect of the disclosure.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic perspective view illustrating an elastic stamp device that is operated to pick up a micro LED during a conventional mass transfer printing process.

FIG. 2 is a schematic perspective view illustrating the micro LED that has been picked up by the elastic stamp device during the conventional mass transfer printing process.

FIG. 3 is a schematic cross-sectional view illustrating a first embodiment of a micro LED according to the present disclosure.

FIG. 4 is a plan view illustrating the first embodiment.

FIG. 5 is a schematic cross-sectional view illustrating a second embodiment of the micro LED according to the present disclosure.

FIG. 6 is a fragmentary schematic cross-sectional view illustrating a third embodiment of the micro LED according to the present disclosure, and a fragmentary schematic enlarged view of a first metallic electrode.

FIG. 7 is a fragmentary schematic enlarged view illustrating the first metallic electrode of a fourth embodiment of the micro LED according to the present disclosure.

FIG. 8 is a fragmentary schematic enlarged view illustrating the first metallic electrode of a fifth embodiment of the micro LED according to the present disclosure.

FIG. 9 is a schematic cross-sectional view illustrating a sixth embodiment of the micro LED according to the present disclosure.

FIG. 10 is a schematic plan view illustrating the sixth embodiment.

FIG. 11 is a schematic cross-sectional view illustrating a seventh embodiment of the micro LED according to the present disclosure.

FIG. 12 is a schematic cross-sectional view illustrating an eighth embodiment of the micro LED according to the present disclosure.

FIG. 13 is a fragmentary schematic cross-sectional view illustrating a second mesa of a ninth embodiment of the micro LED according to the present disclosure.

FIG. 14 is a schematic cross-sectional view illustrating a tenth embodiment of the micro LED according to the present disclosure.

FIG. 15 is a schematic plan view illustrating the tenth embodiment.

FIG. 16 is a schematic cross-sectional view illustrating an eleventh embodiment of the micro LED according to the present disclosure.

FIG. 17 is a schematic cross-sectional view illustrating a twelfth embodiment of the micro LED according to the present disclosure.

FIG. 18 is a fragmentary schematic cross-sectional view illustrating a thirteenth embodiment of the micro LED according to the present disclosure.

FIG. 19 is a schematic cross-sectional view illustrating a fourteenth embodiment of a micro LED according to the present disclosure.

FIG. 20 is a fragmentary cross-sectional view illustrating the fourteenth embodiment.

FIG. 21 is a schematic bottom view illustrating the fourteenth embodiment.

FIG. 22 is a fragmentary schematic cross-sectional view illustrating the fourteenth embodiment.

FIG. 23 is a fragmentary schematic cross-sectional view illustrating an embodiment of a display device.

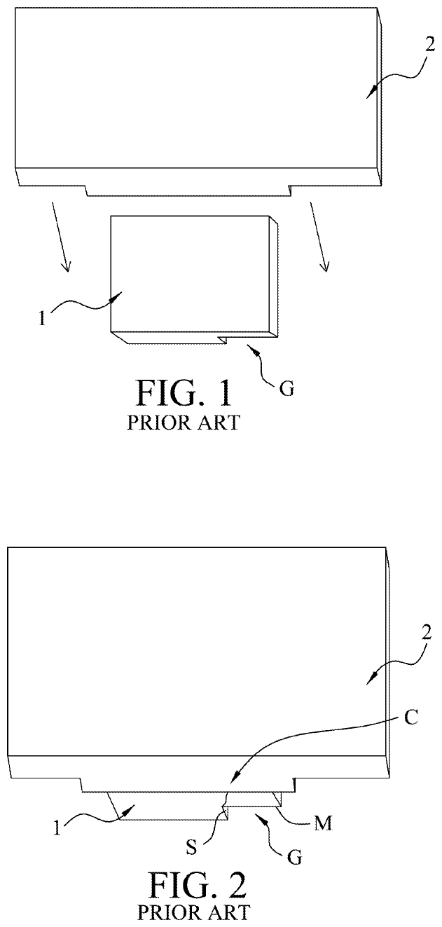

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

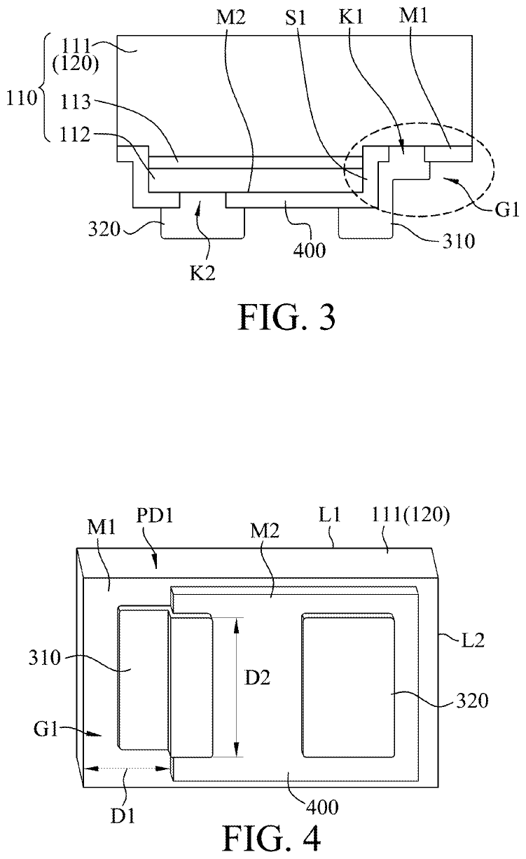

Referring to FIGS. 3 and 4, a first embodiment of a micro light-emitting diode (LED) 100 according to the present disclosure includes a semiconductor layered structure 110 that includes a front side and a back side. The micro LED 100 includes a first metallic electrode 310 disposed on the back side of the semiconductor layered structure 110, and a second metallic electrode 320 disposed on the back side of the semiconductor layered structure 110. In other words, the front side of the semiconductor layered structure 110 is the side that is distal to the first and second metallic electrodes 310, 320 and the back side is the side that is proximate to the first and second metallic electrodes 310, 320. The semiconductor layered structure 110 includes a first-type semiconductor layer 111, an active layer 113, and a second-type semiconductor layer 112 sequentially disposed in a thickness direction from the front side to the back side of the semiconductor layered structure 110. In this embodiment, the semiconductor layered structure 110 is made with a gallium nitride GaN material, indium gallium aluminum InGaAl material or other similar materials. In some embodiments, the first-type semiconductor layer 111 of the semiconductor layered structure 110 provides electrons, and the second-type semiconductor layer 112 of the semiconductor layered structure 110 provides electron holes that recombine with the electrons provided by the first-type semiconductor layer 111 to emit light. After a substrate removal step of the fabrication process, the front side of the semiconductor layered structure 110 is exposed.

The semiconductor layered structure 110 has a first depression (G1) on the back side. In this embodiment, the first depression (G1) is patterned to act as a window for current injection into the semiconductor layered structure 110. The first depression (G1) indents in the thickness direction from the second-type semiconductor layer 112 to the first-type semiconductor layer 111 through the active layer 113 to partially expose the first-type semiconductor layer 111. In this embodiment, because the first-type semiconductor layer 111 is relatively thick, a portion of the first-type semiconductor layer 111 that is free of the first depression (G1) is used as a support base 120. When the semiconductor layered structure 110 is projected on a plane parallel to a long side (L1) of the support base 120, a vertical projection of the semiconductor layered structure 110 has a lateral portion that is completely penetrated by the first depression (G1). The support base 120 is the largest portion of the semiconductor layered structure 110; and the rectangular cross section of the support base 120 is a maximum rectangular cross section of the semiconductor layered structure 110 that is perpendicular to the thickness direction of the semiconductor layered structure 110. A dimension (D1) of the first depression (G1) that extends parallel the long side (L1) of the maximum rectangular cross section is 25% to 60% of a length of the long side (L1). Because a large lateral portion on the back side of the semiconductor layered structure 110 is removed to form the first depression (G1), more space is available for the deposition of the first metallic electrode 310.

The first metallic electrode 310 is electrically connected to the first-type semiconductor structure 111, and the second metallic electrode 320 is electrically connected to the second-type semiconductor structure 112. The first metallic electrode 310 and the second metallic electrode 320 electrically connect the micro LED 100 to an external power source. The semiconductor layered structure 110 has a first mesa (M1) formed at the first-type semiconductor layer 111 in the first depression (G1), a second mesa (M2) formed on the second-type semiconductor layer 112, and a mesa side wall (S1) located between the first mesa (M1) and the second mesa (M2). The first mesa (M1) is located in the first depression (G1). The first metallic electrode 310 is disposed on the first mesa (M1), and the second metallic electrode 320 is disposed on the second mesa (M2). The first metallic electrode 310 is electrically connected to the first semiconductor layer 111, and the second metallic electrode is electrically connected to the second semiconductor layer 112. For example, the second metallic electrode 320 is electrically connected to the second semiconductor layer 112 via a transparent current spreading layer (not shown).

A portion of the first semiconductor layer 111 acts as a support base 120 that provides mechanical support to the semiconductor layered structure 110. When the semiconductor layered structure 110 of the micro LED 100 is viewed from above the front side of the semiconductor layered structure 110, the support base 120 or the semiconductor layered structure 110 is substantially rectangular, and has a length to width ratio that ranges from 1.5 to 5. The support base 120 with such a long narrow design is used in this embodiment to provide adequate mechanical supporting strength. For the support base 120 with a minimum required thickness, when the length to width ratio of the support base 120 ranges from 1.5 to 5, chances of fracturing the support base 120 by an external force may be minimized. However, if the length to width ratio of the support base 120 is greater than 5, the moment arm of any external force applied to the support base 120 is increased and the chances of fracturing the support base 120 is increased. The front side of the semiconductor layered structure 110 has a distance of not greater than 4 μm away from at least a portion of the first depression (G1). In other words, a thickness of at least a portion of the first semiconductor layer 111 within the first depression (G1) is no more than 4 μm. In some embodiments, the thickness of the first semiconductor layer 111 within the first depression (G1) ranges from 1 μm to 4 μm. When viewed from above the back side of the semiconductor layered structure 110, an (depression G1 is hollow space, does not have any surface) area of the first depression (G1) is 25% to 60% of a total surface area of the first semiconductor layer 111. Here, the area of the first depression (G1) does not include the area bordering the second mesa (M2). When the area of the first depression is less than 25% of the surface area of the first semiconductor layer 111, the moment arm of an external force would be small and there is less concern that the support base 120 might fracture. When the area of the first depression is more than 60% of the surface area of the first semiconductor layer 111, the micro LED 100 will lose too much light emitting area and effect the light emission efficiency of the micro LED 100.

The first metallic electrode 310 extends in a direction of the long side (L1) of the support base 120 through the mesa side wall (S1) to the second mesa (M2) until it partially covers the second mesa (M2). This strengthens an area where stresses are concentrated due to the presence of a significant change in thickness of the semiconductor layered structure 110. The first electrode 310 includes multiple metallic layers. An overall thickness of the metallic layers of the first electrode 310 each with a shear modulus of no less than 1000 GPa may range from 30 Å to 1000 Å. By designing the first electrode 310 to have a high shear modulus, when the semiconductor layered structure 110 is subjected to shear forces, it may better resist shear forces and prevent an incidence of being sheared off.

The micro LED 100 further includes an insulating layered unit 400 that is disposed on and covering the semiconductor layered structure 110. The insulating layered unit 400 is located between the first metallic electrode 310 and the second mesa (M2), and between the first metallic electrode 310 and the mesa side wall (S1). The insulating layered unit 400 electrically isolates the first metallic electrode 310 from the second mesa (M2). The insulating layered unit 400 may be made of silicon oxide, silicon nitride, or formed into a distributed Bragg reflector (DBR). In some embodiments, the insulating layered unit 400 is made of silicon dioxide, and has a thickness that ranges from 1000 Å to 10000 Å. In some embodiments, the first metallic electrode 310 extends to cover the first insulating layer 410 on the second mesa (M2), and an area of the first metallic electrode 310 covering the second mesa (M2) has a width (D2) greater than 20% of a length of a short side (L2) of a maximum rectangular cross section of the semiconductor layered structure 110 that is perpendicular to the thickness direction of the semiconductor layered structure 110. In other embodiments, the area of the first electrode 310 covering the second mesa (M2) has a width (D2) ranges from 20% to 90% of the length of the short side (L2) of the maximum rectangular cross section of the semiconductor layered structure 110. This is to ensure the semiconductor layered structure 110 is provided with enough structural strength.

The insulating layered unit 400 has a first opening (K1) formed on the first mesa (M1), and a second opening formed on the second mesa (M2). The first metallic electrode 310 extends from the first opening (K1) on the first mesa (M1) to an outside surface of the insulating layered unit 400. The second metallic electrode 320 extends from the second opening on the second mesa (M2) to an outside surface of the insulating layered unit 400. The insulating layered unit 400 is made of insulating materials. Additionally, the types of the insulating materials included in a portion of the insulating layered unit 400 that corresponds in position to the first mesa (M1) is smaller in number than that included in a portion of the insulating layered unit 400 that corresponds in position to the second mesa (M2).

The first metallic electrode 310 includes multiple metallic layers. The first metallic electrode 310 includes a first metallic layer 311 (see FIG. 6) that contacts the back side of the semiconductor layered structure 110. In some embodiments, the first metallic layer 311 has a shear modulus that is no less that 100 GPa, and a thickness that ranges from 30 Å to 1000 Å. The first metallic layer 311 includes ruthenium (Ru), rhodium (Rh), or chromium (Cr).

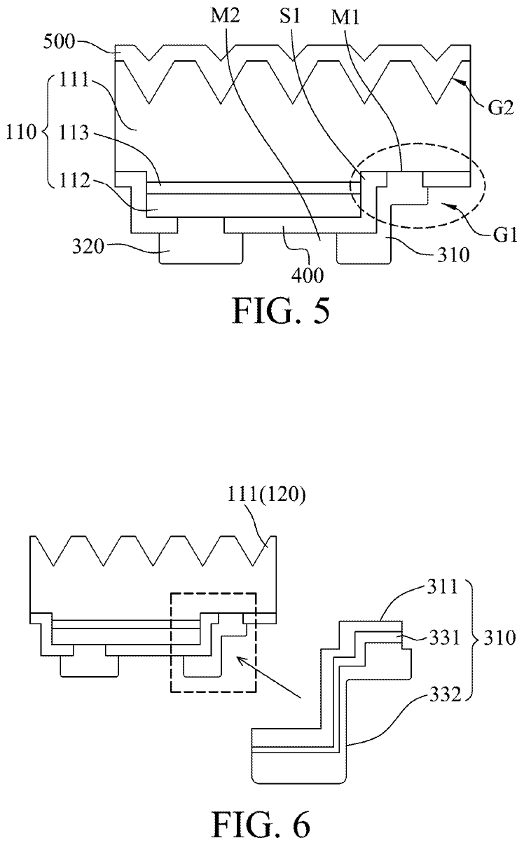

Referring to FIG. 5, a second embodiment of a micro LED 100 according to the present disclosure is similar to the first embodiment. However, in the second embodiment, the semiconductor layered structure 110 may include the first-type semiconductor layer 111 or an un-doped semiconductor layer on the front side. The front side of the semiconductor layered structure 110 is at least partially removed.

The front side of the semiconductor layered structure 110 is patterned or roughened. In some embodiments, the front side of the semiconductor layered structure 110 is roughened to reduce total internal reflection and increase light emission. The roughening may be performed via etching away semiconductor material on the front side of the semiconductor layered structure 110 with an etchant, thereby forming second depressions (G2) that roughens the surface of the front side of the semiconductor layered structure 110. After etching, the first-type semiconductor layer 111 will have a thickness that is no greater than 4 μm when measured in the thickness direction. For example, the first-type semiconductor layer 111 may have a thickness that ranges from 1 μm to 4 μm at a junction of the first mesa (M1) and the second mesa (M2).

By etching the semiconductor layered structure 110 as described above, light efficiency of the micro LED 100 may be increased. For example, the etching may optimize light output shape of the micro LED 100. However, etching may cause unforeseen consequences and may damage the front side of the semiconductor layered structure 110. The micro LED 100 further includes an insulating protective layer 500 that covers the front side of the semiconductor layered structure 110. The insulating protective layer 500 may be partially or completely exposed, and in this embodiments, the insulating protective layer 500 is completely exposed. The insulating protective layer 500 has a thickness that ranges from 2000 Å to 10000 Å. In this embodiment, even though the micro LED 100 includes the insulating protective layer 500 which provides some structural integrity to the front side of the semiconductor layered structure 110 and decreases the chance of the micro LED 100 fracturing when encountering external stress, the micro LED 100 is still not completely immune to fracturing.

In this embodiment, the front side of the semiconductor structure 110 is covered by the insulating protective layer 500, and the first metallic electrode 310 is further strengthen by including multiple metallic layers, both these designs decisions contribute to strengthening the micro LED 100. The first metallic layer 311 of the first metallic electrode 310 contacts the back side of the semiconductor layered structure 110, and has a shear modulus that is no less than 100 GPa. The first metallic layer 311 has a thickness that ranges from 10 Å to 30 Å. By having the insulating protective layer 500 covering the front side of the semiconductor layered structure 110, and with the insulating protective layer 500 having a thickness that ranges from 2000 Å to 10000 Å, the first metallic layer 311 may be made thinner which provides more flexibility when designing the first electrode 310. A thinner first metallic layer 311 has less light absorption.

Referring to FIG. 6, a third embodiment of the micro LED 100 according to the present disclosure is similar to the first embodiment and the second embodiment. However, the design of the first metallic electrode 310 is different. In this embodiment, the first metallic electrode 310 includes a first metallic layer 311 that contacts the back side of the semiconductor layered structure 110, a platinum layer 331, and a bonding layer 332. The platinum layer 331 is disposed on the first metallic layer 311, and the bonding layer 332 is disposed on the platinum layer 331. In this embodiment, the bonding layer 332 includes gold, and the platinum layer 331 has a thickness that ranges from 300 Å to 1000 Å. Even though the platinum layer 331 has a shear modulus that is slightly lower than the first metallic layer 311, the platinum layer 331 may provide sufficient mechanical support when made thicker. In this embodiment, the platinum layer 331 has a thickness of 500 Å in the thickness direction.

In this embodiment, the first metallic layer 311 extends in the direction of the long side (L1) along the support base 120 (the first semiconductor layered structure 110) from the mesa side wall (S1) to the second mesa (M2). The first metallic layer 311 has a shear modulus that is no less than 100 GPa, and a thickness that ranges from 30 Å to 100 Å. In this embodiment, the first metallic layer 311 has a thickness of 50 Å. An area of the first metallic layer 311 covering the second mesa (M2) has a width greater than 20% of a length of the short side (L2) of the maximum rectangular cross section of the semiconductor layered structure 110 that is perpendicular to the thickness direction of the semiconductor layered structure 110.

The first depression (G1) penetrates completely through a lateral portion of the semiconductor layered structure 110 in a direction perpendicular to the thickness direction. The first depression (G1) has an area which occupies a part of an area of the semiconductor layered structure 110 and which has a length that is 25% to 60% of the length of the long side (L1) of the semiconductor layered structure 110. The removal of a considerable lateral portion of the semiconductor layered structure 110 allows more flexibility in the design of the first metallic electrode 310. A difference in area between a surface area of the first metallic electrode 310 on the second mesa (M2) and a surface area of the second metallic electrode 320 on the second mesa (M2) is no greater than 30%. This increases bonding stability during packaging and bonding operations and reduces shear force moment, thereby increasing production yield of the mass transfer process.

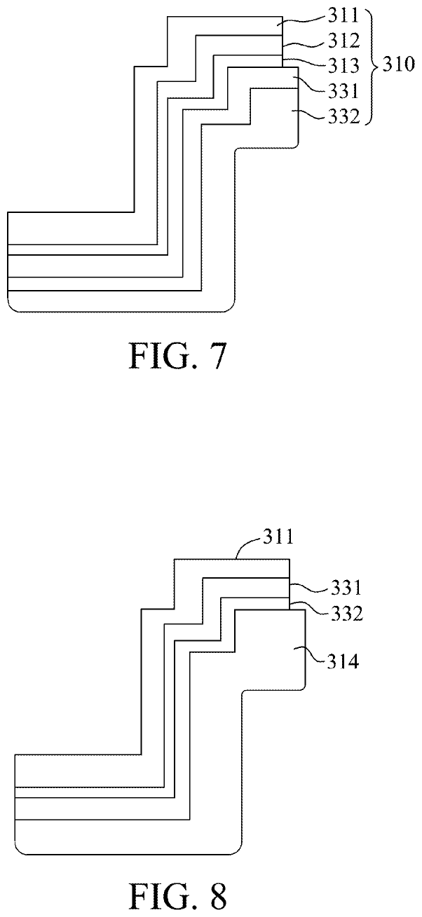

Referring to FIG. 7, a fourth embodiment of the micro LED 100 according to the present disclosure is similar to the first embodiment and the second embodiment. However, the first metallic electrode 310 is designed with a stack of metallic layers in the fourth embodiment. In the fourth embodiment, the first metallic electrode 310 includes a first metallic layer 311, a second metallic layer 312, a third metallic layer 313, a platinum layer 331, and a metallic bonding layer 332 that are sequentially disposed in that order. The second metallic layer 312 is located between the first metallic layer 311 and the third metallic layer 313, and is in direct contact with the first metallic layer 311 and the third metallic layer 313. The first metallic layer 311 and the third metallic layer 313 has a larger shear modulus when compared to the second metallic layer 312. More specifically, the first metallic layer 311 and the third metallic layer 313 has a shear modulus that is no less than 100 GPa. In order to increase reliability, in some embodiments, the thicknesses of the first metallic layer 311 and the third metallic layer 313 are respectively 30 Å and 100 Å. The third metallic layer 313 may be made of ruthenium (Ru), rhodium (Rh), or chromium (Cr). In this embodiment, the first metallic layer 311 has a thickness that ranges from 10 Å to 30 Å, and the third metallic layer 313 has a thickness that ranges from 20 Å to 70 Å. The first metallic layer 311 and the third metallic layer 313 cooperate to provide structural strength to the micro LED 100.

In this embodiment, in order to increase external quantum efficiency of the micro LED 100, the second metallic layer 312 of the first metallic electrode 310 is a metallic reflection layer that is made of aluminum (Al) or silver (Ag), and has a thickness that ranges from 10 Å to 5000 Å. In this way, the micro LED 100 may have good reliability and increased brightness. Additionally, it should be noted that, in this case, the second metallic layer 312 is tasked with light reflection, and the reflection capability of the second metallic layer 312 will be less effective if the thickness of the second metallic layer 312 is less than 10 Å.

Referring to FIG. 8, a fifth embodiment of the Micro LED 100 according to the present disclosure is generally similar to the first and second embodiments. However, in the fifth embodiment, the first metallic electrode includes a first metallic layer 311, a platinum layer 331, a metallic bonding layer 332, and a fourth metallic layer 314 that are sequentially disposed in that order. In this embodiment, the first metallic layer 311 may include ruthenium (Ru), rhodium (Rh), or chromium (Cr), and may have a thickness that ranges from 40 Å to 60 Å. The platinum layer 331 is made of platinum (Pt) and has a thickness that ranges from 100 Å to 1000 Å. The metallic bonding layer 332 is made of gold (Au), and has a thickness that ranges from 100 Å to 1000 Å. The fourth metallic layer 314 includes titanium (Ti), nickel (Ni), tin (Sn), silver (Ag), or copper (Cu).

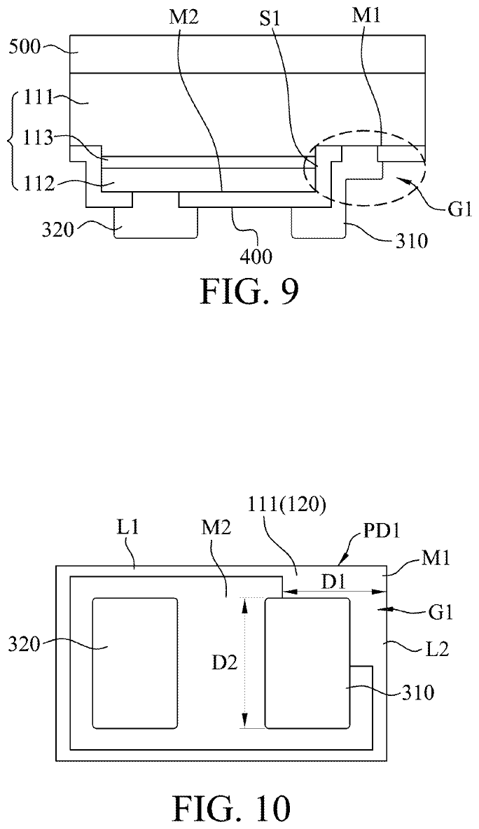

Referring to FIG. 9, a sixth embodiment of the micro LED 100 according to the present disclosure is generally similar to the first embodiment; however, the front side of the semiconductor layered structure 110 is not patterned or roughened. The support base 120 of the semiconductor layered structure 110 is designed with a relatively small thickness. With current LED fabrication technology, a support base is usually required to be thicker than 4 μm. For example, in a conventional standard sized chip using a sapphire substrate, the sapphire substrate is thicker than 50 μm. In contrast to this, the design of this embodiment is without a growth substrate since the growth substrate is peeled off during the fabrication process. Since the first depression (G1) completely penetrates through a lateral portion of the semiconductor layered structure 110, the semiconductor layered structure 110 of the micro LED 100 has a stress concentrated area and a stress defect or stress deficient area; the stress defect area exists at the junction between the first mesa (M1) and the second mesa (M2). In this embodiment, a portion of the first-type semiconductor layer 111 at the first mesa (M1) has a thickness that ranges from 1 μm to 4 μm. The semiconductor layered structure 110 has a depression area that occupies a part of an area of the semiconductor layered structure 110. The depression area has a length that is 25% to 60% of a length of the long side (L1) of the semiconductor layered structure 110 and that extends parallel the long side (L1). With this design, a large lateral portion of the semiconductor layered structure 110 may be removed to allow more flexibility in designing the first metallic electrode 310. In current conventional micro LED design, even without roughening or patterning of a front side of a semiconductor layered structure, the conventional micro LED may break or fracture under stress and does not have good structural stability.

Referring to FIG. 10, in a variation of this sixth embodiment, the first depression (G1) penetrates through and opens at the surface (PD1) on only one of two opposite long sides (L1) of the semiconductor layered structure 110. The depression area of the first depression (G1) has a length that is 30% to 80% of the short side (L2) of the semiconductor layered structure 110 when measured along the short side (L2), and the support base 120 has a thickness that is less than 3 μm. The first electrode 310 extends in the direction of the long side (L1) of the support base 120 through the mesa side wall (S1) to cover the second mesa (M2). The first metallic electrode 310 includes a plurality of metallic layers, some of which have a shear modulus that is no less than 100 GPa and a total thickness that ranges from 30 Å to 1000 Å. This provides structural support for the first metallic electrode 310.

In another variation of the sixth embodiment, the first metallic electrode 310 extends in the direction of the long side (L1) along the support base 120 to the second mesa (M2) via the mesa side wall (S1) so as to cover the second mesa (M2). The first metallic electrode 310 includes a plurality of metal layers, of which a first metallic layer 311 is electrically connected to the back side of the semiconductor layered structure 110. The first metallic layer 311 has a shear modulus that is no less than 100 GPa, and a thickness that ranges from 30 Å to 1000 Å. The first metallic layer 311 may include ruthenium (Ru), rhodium (Rh), or chromium (Cr).

In still another variation of the six embodiment, the first metallic electrode 310 includes a first metallic layer 311, a second metallic layer 312, and a third metallic layer 313 (see FIG. 7) that are sequentially disposed in that order in the thickness direction. The second metallic layer 312 is located between the first metallic layer 311 and the third metallic layer 313, and is in direct contact with the first metallic layer 311 and the third metallic layer 313. The first metallic layer 311 and the third metallic layer 313 has a shear modulus that is greater than the second metallic layer 312. The first metallic layer 311 and the third metallic layer 313 has a shear modulus that is no less than 100 GPa. In order to ensure structural reliability, in this embodiment, a total thickness of the first metallic layer 311 and the third metallic layer 313 ranges from 30 Å to 100 Å.

In this embodiment, the micro LED 100 may have the features of any of the previously described embodiments of the disclosure, except the feature of having front side of the semiconductor layered structure 110 being roughened or patterned (such as the second embodiment). The design of the first metallic electrode 310 or the insulating protective layer 500 is modified in this embodiment to improve the structural integrity of the micro LED 100. The insulating protective layer 500 may have a thickness that ranges from 2000 Å to 10000 Å. With this amount of thickness, considerations of the rigidity of the first metallic layer 311 may be relaxed as the insulating protective layer 500 will provide sufficient stiffness for the micro LED 100, allowing the micro LED to embrace more flexible designs, such as, reducing the thickness of the first metallic layer 311 which decreases light absorption. Alternatively, the insulating protective layer 500 may have a thickness that ranges from 5000 Å to 10000 Å. In this case the structural strength provided by the first metallic layer 311 is no longer a consideration, and the first metallic layer 311 may be made of a softer metal.

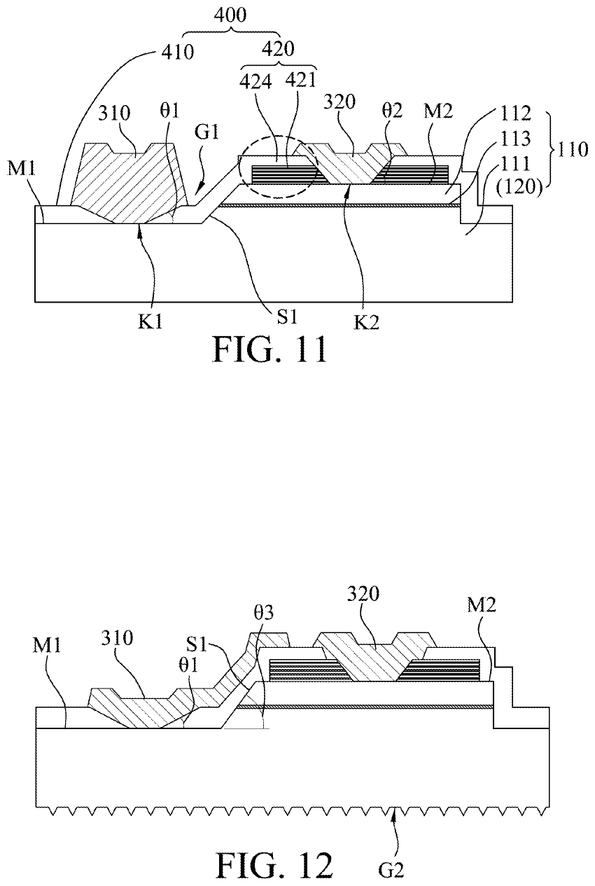

Referring to FIG. 11, a seventh embodiment of the micro LED 100 according to the present disclosure is generally similar to the first embodiment. In this embodiment, the semiconductor layered structure 110 has a first depression (G1) on the back side that indents in the thickness direction from the second-type semiconductor layer 112 to the first-type semiconductor layer 111 through the active layer 113 to partially exposes the first-type semiconductor layer 111. The semiconductor layered structure 110 has a first mesa (M1) formed in the first depression (G1), a second mesa (M2) formed on the second-type semiconductor layer 112, and a depression side wall (S1) located between the first mesa (M1) and the second mesa (M2).

A first metallic electrode 310 is disposed on the back side of the semiconductor layered structure 110, and electrically connected to the first-type semiconductor structure 111. A second metallic electrode 310 is disposed on the back side of the semiconductor layered structure 110, and electrically connected to the second-type semiconductor structure 112.

The micro LED 100 has an insulating layered unit 400 that extends from the first mesa (M1) to the second mesa (M2). A portion of the insulating layered unit 400 on the first mesa (M1) has a first insulating layer 410 disposed on the first mesa (M1), and a portion of the insulating layered unit 400 on the second mesa (M2) has a second insulating layer 420 which has a first sublayer 421 covering the second mesa (M2), and a second sublayer 424 covering the first sublayer 421. The first insulating layer 410 has a first opening (K1) formed on the first mesa (M1). The first metallic electrode 310 is at least partially disposed on the first mesa (M1). The first metallic electrode 310 extends from inside of the first opening (K1) on the first mesa (M1) to an outside surface of the first insulating layer 410. The second insulating layer 420 is disposed on the second mesa (M2). The first sublayer 421 of the second insulating layer 420 has a second opening (K2) formed on the second mesa (M2). The second metallic electrode 320 is at least partially disposed in the second opening (K2). The second metallic electrode 320 extends from the second opening (K2) on the second mesa (M2) to above the second insulating layer 420. The second insulating layer 420 is composed of a number of dielectric materials and this number is higher than the number of dielectric materials composing the first insulating layer 410 of the insulating layered unit 400.

In this embodiment, the second insulating layer 420 has a thickness that is greater than a thickness of the first insulating layer 410. A ratio of the thickness of the first insulating layer 410 to the thickness of the first sublayer 421 of the second insulating layer 420 ranges from ¼ to ⅔. In this embodiment, the first insulating layer 410 has a thickness that ranges from 0.5 μm to 2 μm, and the first sublayer 421 of the second insulating layer 420 has a thickness that ranges from 1 μm to 3 μm. The first insulating layer 410 extends from the first mesa (M1) to the second mesa (M2) via the first mesa side wall (S1) and forms a contiguous structure with the second sublayer 424 of the second insulating layer 420. Thus, the second insulating layer 420 includes a part of the first insulating layer 410.

The first insulating layer 410 may include one type of dielectric material and the second insulating layer 420 may include at least two types of dielectric materials. In this embodiment, the first insulating layer 410 includes one dielectric material which is silicon dioxide, and the second insulating layer 420 includes two dielectric materials that are silicon dioxide, and titanium dioxide. In some variations of this embodiment, the dielectric material included in the first insulating layer 410 is either silicon dioxide, or silicon nitride, and the dielectric materials included in the second insulating layer 420 are silicon nitride, silicon dioxide, and titanium dioxide. This reduces the difficulty of controlling the etching of the first insulating layer 410.

A boundary wall of the insulating layered unit 400 that bounds the first opening (K1) has a first inclined angle (01) relative to a surface of the first mesa (M1), a boundary wall of the insulating layered unit 400 that bounds the second opening (K2) has a second inclined angle (θ2) relative to a surface of the second mesa (M2). The first inclined angle (θ1) is no greater than the second inclined angle (θ2). The first inclined angle (θ1) ranges from 20° to 55°, and the second inclined angle (θ2) ranges from 30° to 60°.

In some embodiments, when viewed from above the back side of the semiconductor structure 110, the micro LED 100 has a rectangular shape. The semiconductor layered structure 110 of the micro LED 100 has a maximum rectangular cross section that is perpendicular to the thickness direction. The maximum rectangular cross section of the semiconductor structure 110 has a short side (L2) with a length not greater than 15 μm, and each lateral side of an area of the first mesa (M1) is not greater than 15 μm. In the semiconductor layered structure 110 of the micro LED 100, since part of the active layer 113 has to be sacrificed for forming the first mesa (M1), the area of the second mesa (M2) is advantageous compared to that of the first mesa (M1). Therefore the first mesa (M1) has a mesa area that is smaller than a mesa area of the second mesa (M2). More specifically, a ratio of the mesa area of the first mesa (M1) to the mesa area of the second mesa (M2) ranges from ½ to ⅘. The second opening (K2) is formed on the second mesa (M2), and a minimum diameter of the second opening (K2) is no less than a minimum diameter of the first opening (K1). A minimum diameter of the first opening (K1) ranges from 1 μm to 3 μm, and a minimum diameter of the second opening (K2) ranges from 1 μm to 5 μm.

Referring to FIG. 12, an eighth embodiment of the micro LED 100 according to the present disclosure is generally similar to the first embodiment; however, the eight embodiment is different in that the first metallic electrode 310 extends from the first opening (K1) on the first mesa (M1) to a portion of the second mesa (M2) via the mesa side wall (S1). This is to increase the structural strength of the micro LED 100 and prevent breakage of the support base 120 (semiconductor layered structure 110) at the first mesa (M1) during mass transfer, especially, when the support base 120 is very thin at the first mesa (M1). The mesa side wall (S1) is provided with a slope design so that the semiconductor layered structure 110 has a gradually changing thickness. The mesa side wall (S1) is inclined relative to a plane coplanar with the first mesa (M1) at an angle (θ3) that is less than 70°. In some embodiments, a boundary wall of the second opening (K2) (i.e., a boundary wall of the insulating layered unit 400 that bounds the second opening) has multiple slopes inclined at different angles relative to the surface of the second mesa (M2). In these cases, all the different angles are greater than the first inclined angle (θ1).

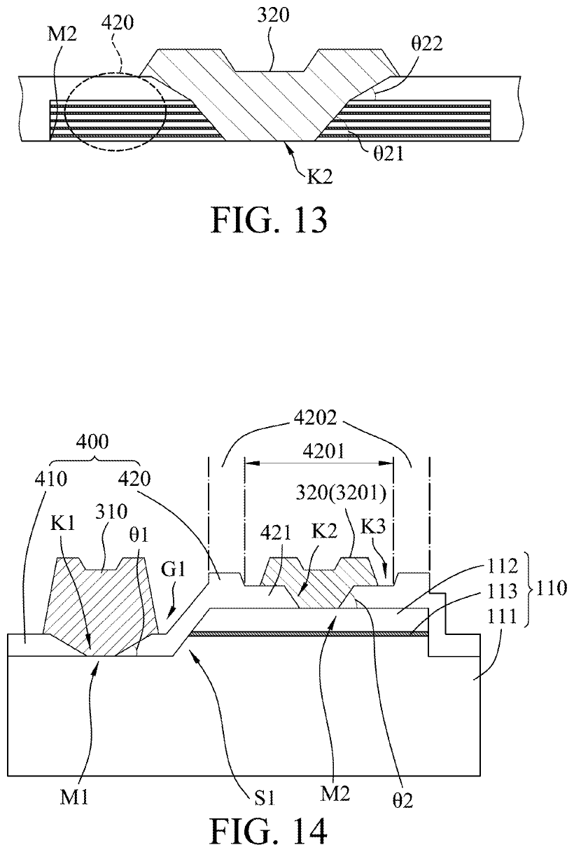

Referring to FIG. 13, a ninth embodiment of the micro LED 100 according to the present disclosure is generally similar to the first embodiment. However, in order to increase reliability and quality of the second metallic electrode, in this embodiment, the first insulating layer 410 covers the first sublayer 421. More specifically, the first insulating layer 410 extends form the first mesa (M1) to the second mesa (M2) via the mesa side wall (S1) and forms a contiguous structure in which the first insulating layer 410 covers the first sublayer 421. A boundary wall of the insulating layered unit 400 that bounds the second opening (K2) (i.e., the boundary wall of the first sublayer 421 that bounds the second opening (K2)) has a sloped surface with a varying inclined angle relative to a surface of the second mesa (M2) (see FIG. 22). The varying inclined angle including at least a first angle (θ21) and a second angle (θ22). In this embodiment, the sloped surface has the first angle (θ21) relative to the second mesa (M2) near the second insulating layer (420), and the sloped surface of the second metallic electrode 320 has the second angle (θ22) near the first insulating layer 410 relative to the second mesa (M2). Furthermore, the first angle (θ21) is greater than the second angle (θ22) (see FIG. 22).

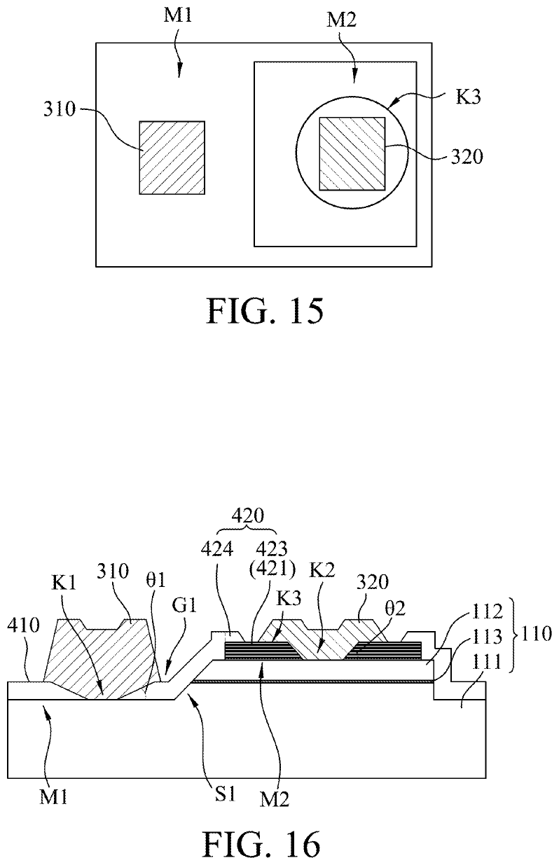

Referring to FIGS. 14 and 15, a tenth embodiment of the micro LED 100 is generally similar to the first embodiment. However, the insulating layered unit 400 has the first insulating layer 410 and the second insulating layer 420. Each of the first and second insulating layers 410, 420 includes silicon oxide, silicon nitride or titanium oxide. The first insulating layer 410 has a first opening (K1) formed on the first mesa (M1). The first metallic electrode 310 is at least partially disposed on the first mesa (M1), and extends from the first opening (K1) on the first mesa (M1) to above the first insulating layer 410. A boundary wall of the first insulating layer 410 of the insulating layered unit 400 that bounds the first opening (K1) has a first inclined angle (θ1) relative to the first mesa (M1). The second sublayer 424 of the second insulating layer 420 is a part of the first insulating layer 410. The first insulating layer 410 extends from the first mesa (M1) to the second mesa (M2) via the mesa side wall (S1). The second insulating layer has the second opening (K2) formed on the second mesa (M2). The second metallic electrode 320 is partially disposed in the second opening (K2). The second electrode 320 extends from the second opening (K2) of the second mesa (M2) to the second insulating layer 420. The second opening (K2) has a minimum diameter that ranges from 1 μm to 5 μm. In this embodiment the minimum diameter of the second opening (K2) is the bottom diameter. The bottom diameter of the second opening (K2) may be increased to facilitate etching characteristics and decrease the second inclined angle (θ2) between the boundary wall of the second insulating layer 420 that bounds the second opening (K2) relative to a surface of the second mesa (M2). In this embodiment, the second insulating layer 420 has a thickness that is greater than a thickness of the first insulating layer 410. More specifically, a ratio of the thickness of the first insulating layer 410 to the thickness of the second insulating layer 420 ranges from ¼ to ⅔. In some embodiments, the ratio of the thickness of the first insulating layer 410 to the thickness of the second insulating layer 420 ranges from ⅔ to 2. In this embodiment, the first insulating layer 410 has a thickness that ranges from 0.5 μm to 2 μm, and the second insulating layer 420 has a thickness that ranges from 1 μm to 3 μm. By making the first insulating layer 420 thinner the yield rate of the first metallic electrode 310 may be increased and edges of the first opening (K1) may be prevented from being damaged.

In FIG. 14, the second insulating layer 420 includes a first part 4201 that is covered by a top pad portion 3201 of the second metallic electrode 320, and a second part 4202 that is not covered by the top pad portion 3201 of the second metallic electrode 320. The first part 4201 of the second insulating layer 420 does not have the first insulating layer 410. In other words, the first insulating layer 410 is not present below the top pad 3201 of the second metallic electrode 320. In an example, the first part 4201 of the second insulating layer 420 does not include the first insulating layer 410 and is made of silicon dioxide and titanium dioxide, and the second part 4202 of the second insulating layer 420 includes silicon nitride, silicon dioxide, and titanium dioxide. In another example, the materials in the first and second insulating layers 410, 420 are different; for example, the first insulating layer 410 includes silicon nitride and silicon oxide, and the second insulating layer 420 includes silicon nitride, silicon oxide, and titanium oxide. In terms of insulating materials, the more dielectric materials composing the insulating layer the more difficult it will be to control the angle of the boundary wall of the second insulating layer 420 when forming the second opening (K2) on the second mesa (M2). When the second opening (K2) has a diameter ranging from 1 μm to 5 μm, the second opening (K2) may be suitably enlarged to facilitate etching characteristics and reduce the inclined angle of the boundary wall of the second opening (K2) is reduced. If both the first insulating layer 410 and the second insulating layer 420 are disposed below the top pad of the second metallic electrode 320, controlling the second inclined angle (θ2) while forming the second opening (K2) will be even more difficult. This is due to the different etching/removal characteristics of the several materials used for the first insulating layer 410 and the second insulating layer 420. In this embodiment, the thickness and number of dielectric materials of the insulating layered unit 400 under the top pad 3201 of the second metallic electrode 320 are reduced because the first insulating layer 410 (i.e., the second sublayer 424) is not present below the top pad 3201 of the second metallic electrode 320. In this embodiment, a third opening (K3) is formed above the second opening (K2) and disposed in the second sublayer 424 of the insulating layered unit 400 on the second mesa (M2). The first sublayer 421 of the second insulating layer 420 is exposed within the third opening (K3), and the top pad 3201 of the second electrode 320 covers and contacts the first sublayer 421

In this embodiment, the micro LED 100 has a rectangular shape, and the semiconductor layered structure 110 of the micro LED 100 has a maximum rectangular cross section that is perpendicular to the thickness direction. The maximum rectangular cross section has a short side (L2) with a length that is no greater than 15 μm. Additionally, each lateral side of the first mesa (M1) has a length no greater than 15 μm. Generally, micro LEDs are limited by their microscopic dimensions, and may not be provided with mesa areas like those of conventional LEDs. In this embodiment the first mesa (M1) has a mesa area that is smaller than a mesa area of the second mesa (M2). More specifically a ratio of the mesa area of the first mesa (M1) to the mesa area of the second mesa (M2) ranges from ½ to ⅘. In this embodiment, the first mesa (M1) is reduced in size so that more space may be allocated for the second mesa (M2) which is the main light emitting area of the micro LED 100.

Since the first opening (K1) is disposed on the first mesa (M1) and the first mesa (M1) has a smaller mesa area, the micro LED 100 will be more efficient. Therefore, in this embodiment, the first mesa (M1) is designed to have a mesa area that is smaller than the mesa area of the second mesa (M2). The first opening (K1) has a minimum diameter that ranges from 1 μm to 3 μm, and the second opening (K2) has a minimum diameter that ranges from 1 μm to 5 μm. In this embodiment, the minimum diameter of the first opening (K1) is a bottom diameter of the first opening (K1), and the minimum diameter of the second opening (K2) is the bottom diameter of the second opening (K2). The second opening (K2) is formed on the second mesa (M2) and has a bottom diameter that is no less than a bottom diameter of the first opening (K1). In this embodiment, the bottom diameters of the first and second openings (K1, K2) are their respective minimum diameters. A boundary wall of the first insulating layer 410 of the insulating layered unit 400 that bounds the first opening (K1) has a first inclined angle (θ1) relative to a surface of the first mesa (M1). A boundary wall of the second insulating layer 420 of the insulating layered unit 400 has a second inclined angle (θ2) relative to a surface of the second mesa (M2). The first inclined angle (θ1) is no greater than the second inclined angle (θ2). The first inclined angle (θ1) may range from 20° to 55°, and the second inclined angle (θ2) may range from 30° to 60°. In other embodiments, the first inclined angle (θ1) may range from 20° to 45°, and the second inclined angle (θ2) may range from 20° to 60°. In the micro LED 100 of this embodiment, the dielectric material of the insulating layered unit 400 is controlled and adjusted in terms of material type and thickness to reduce the first inclined angle (θ1) of the boundary wall of the first insulating layer 410 relative to first mesa (M1). This allows better control of the first inclined angle (θ1) when forming the first opening (K1).

Referring to FIG. 16, an eleventh embodiment of the micro LED 100 according to the present disclosure is generally similar to the first embodiment. However, the eleventh embodiment is different in that the first sublayer 421 of the second insulating layer 420 located on the second mesa (M2) is an insulating reflective layer 423 that is formed with a distributed Bragg reflector (DBR) layer. For example, the insulating reflective layer 423 may be a DBR reflective layer formed by alternating layers of silicon dioxide and titanium dioxide; the number of periods of the DBR reflective layer is larger than 3. In this embodiment, the first insulating layer 410 extends from the first mesa (M1) to the second mesa (M2) via the mesa side wall (S1) and covers the insulating reflective layer 423 of the second insulating layer 420. The third opening (K3) is formed in the second sublayer 424 that covers the first sublayer 421 of the second insulating layer 420. Hence the third opening (K3) exposes the insulating reflective layer 423 (first sublayer 421). A perpendicular projection of the second opening (K2) onto a plane parallel to the back side of the semiconductor layered structure entirely falls within a perpendicular projection of the third opening (K3) onto the same plane. In this embodiment, the boundary walls of the first and second sublayers 421, 424 are exposed within the third opening (K3), and a top pad 3201 of the second metallic electrode 320 is disposed in the third opening (K3). By reducing the thickness and number of dielectric materials that compose the second insulating layer 420 under the top pad 3201 of the second metallic electrode 320, options for etching the semiconductor layered structure 110 may be expanded. For example, wet etching or dry etching methods may be adopted for etching for the etching of the micro LED 100. Additionally, the inclined angle of the boundary wall of the second opening (K2) may be made more controllable. In this embodiment, a dry etching method is used.

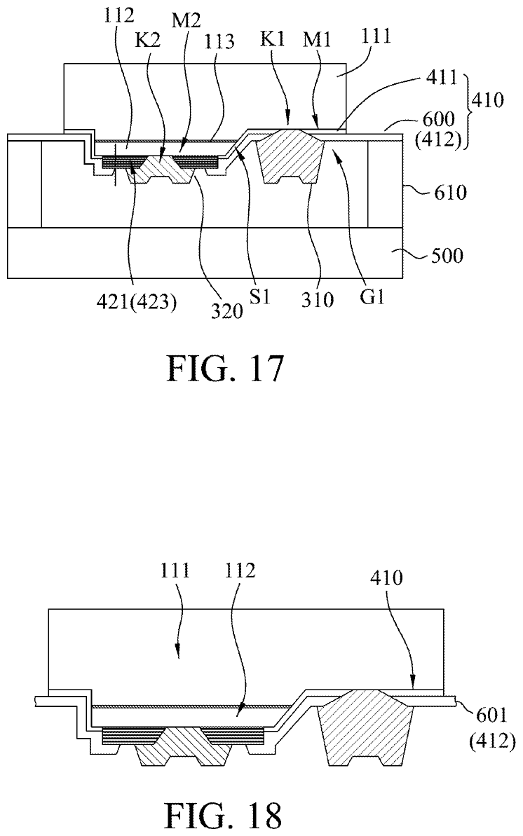

Referring to FIG. 17, a twelfth embodiment of the micro-light emitting device 100 is adapted for photolithography and includes a substrate 500, a micro LED 100 and a bridge arm 600. The first insulating layer 410 includes a first dielectric sublayer 411 and a second dielectric sublayer 412 that is different from the first dielectric sublayer 411. The bridge arm 600 is made of the same material(s) as the second dielectric layer 412. The first insulating layer 410 is disposed on the semiconductor layered structure 110. The first dielectric sublayer 411 is disposed between the second dielectric sublayer 412 and the semiconductor layered structure 110. The second dielectric sublayer 412 is used to connect the bridge arm 600 to the micro LED 100 (main body). In this embodiment, the main body is the same structure with the micro LED 100, the micro LED 100 is not limited to including the bridge arm 600, and the first dielectric sublayer 411 covers a surface of the second dielectric sublayer 412. In this embodiment, a gap is formed between the main body and the substrate 500, and the second dielectric layer 412 has a thickness that is greater than a thickness of the first dielectric layer 411. The bridge arm 600 may be directly connected to the substrate 500, or in some embodiments, the bridge arm 600 may be indirectly connected to the substrate 500 via piers 610.

The micro-light emitting device 100 may further include a second insulating layer 420. The second insulating layer 420 is disposed on the second mesa (M2). The first insulating layer 410 extends from the first mesa (M1) to the second mesa (M2) via the first mesa side wall (S1). The second insulating layer 420 has the second opening (K2) formed on the second mesa (M2). The first insulating layer 410 covers the second insulating layer 420. The second metallic electrode 320 is at least partially disposed in the second opening (K2), and extends from the second opening (K2) to the second insulating layer 420. The second insulating layer 420 includes a first part 4201 where the second metallic electrode 320 is formed, and a second part 4202 where no second metallic electrode 320 is formed. The first insulating layer 410 covers the second part 4202 of the second insulating layer 420 but does not cover the first part 4201 of the second insulating layer 420.

In this embodiment, the second dielectric sublayer 412 has a thickness that ranges from 1.5 times to 10 times a thickness of the first dielectric sublayer 411. The first dielectric sublayer 411 is connected to the semiconductor layered structure 110. The second dielectric sublayer 412 is made of silicon nitride. In this embodiment, the first dielectric sublayer 411 has a thickness that ranges from 0.1 μm to 0.5 μm in the thickness direction, and the second dielectric sublayer 412 has a thickness that ranges from 0.15 μm to 0.3 μm in the thickness direction. In other embodiments, the second dielectric layer may have a thickness that ranges from 0.3 μm to 0.8 μm or 0.8 μm to 2 μm. The width of the second dielectric sublayer 412 ranges from 1 μm to 20 μm in length.

In some embodiments, the first dielectric sublayer 411 is made of a silicon oxide material such as silicon dioxide, and the second dielectric sublayer 412 is made of silicon nitride. The first dielectric sublayer 411 includes at least one material with negative normal stress, and the second dielectric sublayer 412 includes at least one material with positive normal stress.

In this embodiment, the first dielectric sublayer 411 thinner than the second dielectric sublayer 412 is used as a stress adjustment layer to manage contact stresses between the second dielectric sublayer 412 and the semiconductor layered structure 110. It should be noted that, the thickness of the connecting layer (e.g., the first dielectric sublayer 411 has a considerable influence on yield rates. By partially removing the bridge arm 600 and the first dielectric sublayer 411 that spans the semiconductor layered structure 110, both the stress characteristics and the yield rates of the micro LED 100 may be optimized.

Referring to FIG. 18, a thirteenth embodiment according to the present disclosure is shown. In this embodiment, the micro LED 100 shown in FIG. 17 has a residual part of the bridge arm 600 resulting from fracture of the bridge arm 600 after a mass transfer printing process. More specifically, the first insulating layer 410 includes a residual bridge arm 601, and the second insulating layer 420 may include a silicon oxide material and a titanium oxide material as dielectric materials. For example, the dielectric materials of the second insulating layer 420 may be silicon dioxide and titanium dioxide. In some embodiments, the second insulating layer 420 may include a silicon oxide material, a silicon nitride material, and a titanium oxide material as the dielectric materials. For example, the second insulating layer 420 may include silicon dioxide, silicon nitride, and titanium dioxide as dielectric materials. The residual bridge arm 601 is the second dielectric sublayer 412.

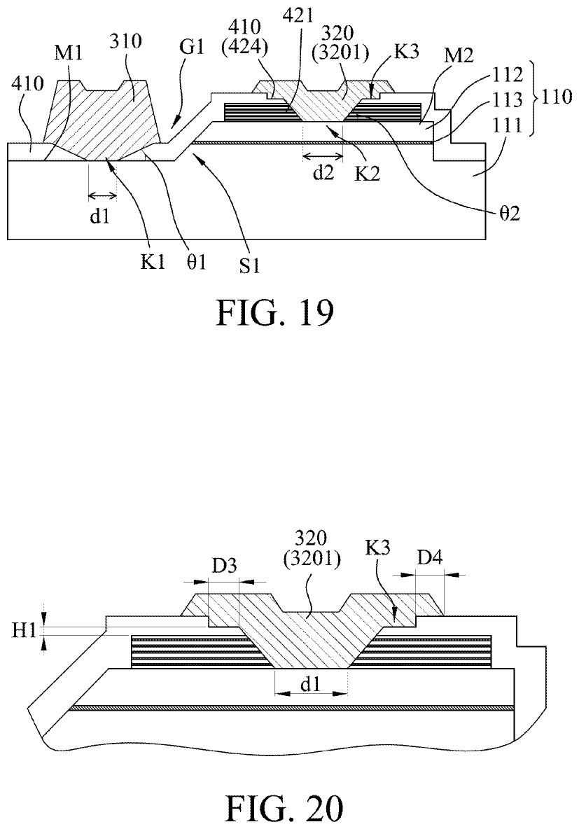

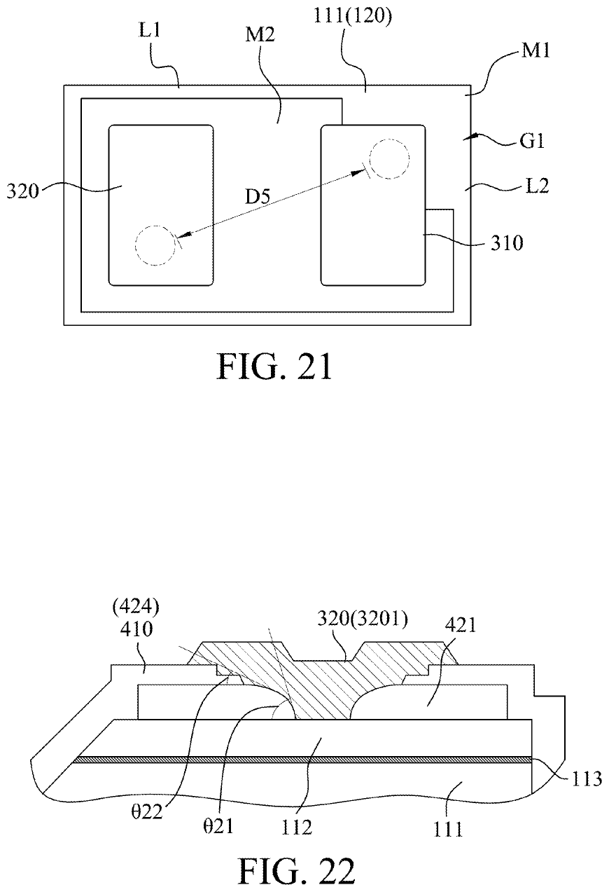

Referring to FIGS. 19 to 21, a fourteenth embodiment of the micro LED 100 is generally similar to the first embodiment. As mentioned previously, the second metallic electrode 320 extends from inside of the second opening (K2) to the third opening (K3). A boundary wall of the insulating layered unit 400 that is exposed in the third opening (K3) includes the first insulating layer 410 (second sublayer 424). Particularly, it is the boundary wall of the first insulating layer 410 that is exposed in the third opening (K3). The second metallic electrode 320 extends outwardly from inside of the third opening (K3) to an outside surface of the first insulating layer 410 so as to partially cover the outside surface; a portion of the second metallic electrode 320 that covers the outside surface has a width (D4) ranging from 0.1 μm to 10 μm. The first sublayer 421 of the second insulating layer 420 is an insulating reflective layer that includes a titanium oxide material. For example, the first sublayer 421 of the second insulating layer 420 may be a distributed Bragg reflector composed of silicon dioxide and titanium dioxide. In this embodiment, the portion of the second metallic electrode 320 that covers the outside surface of the first insulating layer 410 provides a sufficient coverage which helps to strengthen the first insulating layer 410 and prevent the first insulating layer 410 from cracking at an outside of the third opening K3.

In this embodiment, the boundary wall of the second sublayer 424 of the second insulating layer 420 is exposed within the third opening (K3), and has a stepped surface that faces toward an outside of the third opening (K3) and that is covered by the second metallic electrode 320. The stepped surface of the second sublayer 424 that is exposed within the third opening (K3) has a height (H1) that ranges from 0.01 μm to 0.2 μm and that is measured from an interface of the first and second sublayers 421, 424 of the second insulating layer 420.

At least one of the first metallic electrode 310 and the second metallic electrode 320 includes one of chromium, aluminum, titanium, platinum, and gold. In this embodiment, the first sublayer 421 of the second insulating layer 420 is covered by the first insulating layer 410 on the second mesa (M2), and a ratio of a thickness of the first insulating layer 410 to a thickness of the first sublayer 421 of the second insulating layer 420 ranges from ¼ to ⅔, or ⅔ to 2. By reducing the thickness of the first insulating layer 410, the production quality of the first electrode 310 may be improved.

In this embodiment, a boundary wall of the insulating layered unit 400 that bounds the first opening (K1) has a first inclined angle (θ1) relative to the surface of the first mesa (M1), a boundary wall of the insulating layered unit 400 that bounds the second opening (K2) has a second inclined angle (θ2) relative to the surface of the second mesa (M2). The first inclined angle (θ1) is no greater than the second inclined angle (θ2). The first inclined angle (θ1) ranges from 20° to 55°, and the second inclined angle (θ2) ranges from 30° to 60+θ.

In this embodiment the second opening (K2) is formed on the second mesa (M2), and a minimum diameter (d2) of the second opening (K2) is no less than a minimum diameter (d1) of the first opening (K1). The minimum diameter (d1) of the first opening (K1) ranges from 1 μm to 3 μm, and the minimum diameter (d2) of the second opening (K2) ranges from 1 μm to 5 μm, or 5 μm to 10 μm.

In this embodiment, micro LED 100 has a rectangular shape and the semiconductor layered structure 110 of the micro LED 100 has a maximum rectangular cross section that is perpendicular to the thickness direction. The maximum rectangular cross section has the short side (L2) with a length that is no greater than 15 μm, or that ranges from 15 μm to 50 μm, and each lateral side of the first mesa (M1) is no greater than 15 μm, or ranges from 15 μm to 50 μm.

A minimum distance (D5) between the first opening (K1) and the second opening (K2) ranges from 5 μm to 20 μm, or 20 μm to 35 μm. The minimum distance (D5) is measured from the deepest ends of the first and second openings (K1, K2).

Referring to FIG. 22, a boundary wall of the insulating layered unit (400) that bounds the second opening (K2) (specifically, a boundary wall of the first sublayer 421 of the second insulating layer 420 that bounds the second opening (K2)), has a sloped surface with a varying inclined angle relative to the surface of the second mesa (M2). The varying inclined angle including a first angle (θ21) and a second angle (θ22). The second angle (θ22) is more proximate to an outside of the third opening (K3) than the first angle (θ21), and the second angle (θ22) is smaller than the first angle (θ21). The first sublayer 421 of the second insulating layer 420 defining the second opening (K2) has a curved corner with a gradually decreasing slope which helps to increase coverage of the second metallic electrode 320.

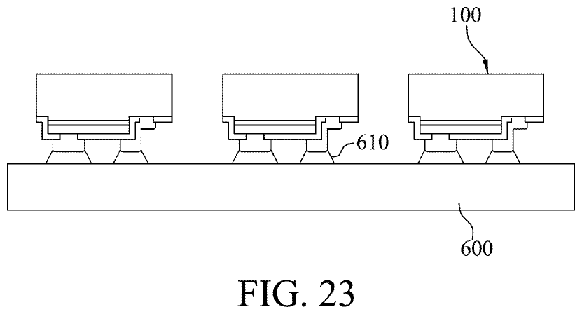

Referring to FIG. 23, in a fifteenth embodiments of the present disclosure, a display device includes a printed circuit board (PCB) 600, and a plurality of micro LEDs 100. The micro LEDs 100 are mounted on the PCB 600 via conducting wires or solder plates 610. The micro LEDs 100 may be any of the previously described embodiments of the disclosure.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A micro light-emitting diode (LED) comprising:
a semiconductor layered structure including a front side and a back side, said semiconductor layered structure further including a first-type semiconductor layer, an active layer, and a second-type semiconductor layer sequentially disposed in a thickness direction from said front side to said back side of said semiconductor layered structure, said semiconductor layered structure having a first depression on said back side that indents in said thickness direction from said second-type semiconductor layer to said first-type semiconductor layer through said active layer to partially expose said first-type semiconductor layer, a first mesa formed at said first-type semiconductor layer, a second mesa formed at said second-type semiconductor layer, and a mesa side wall located between said first mesa and said second mesa;
a first metallic electrode disposed on said back side of said semiconductor layered structure, and electrically connected to said first-type semiconductor structure;
a second metallic electrode disposed on said back side of said semiconductor layered structure, and electrically connected to said second-type semiconductor structure; and
an insulating layered unit disposed on and covering said semiconductor layered structure, and extending from said first mesa to said second mesa, a portion of said insulating layered unit on said first mesa having a first insulating layer disposed on said first mesa, a portion of said insulating layered unit on said second mesa having a second insulating layer that has a first sublayer covering said second mesa, and a second sublayer covering said first sublayer;
wherein said first insulating layer has a first opening formed on said first mesa, said first metallic electrode extending from inside of said first opening on said first mesa to an outside surface of said first insulating layer;
wherein said first sublayer has a second opening formed on said second mesa, and said second metallic electrode being partially disposed in said second opening;
wherein a third opening is formed above said second opening and in said second sublayer; and
wherein a perpendicular projection of said second opening onto a plane parallel to said back side of said semiconductor layered structure entirely falls within a perpendicular projection of said third opening onto the plane, said second metallic electrode extends from inside of said second opening to said third opening, and a boundary wall of said second insulating layer that is exposed within said third opening includes at least one of said first sublayer or said second sublayer.

2. The micro LED as claimed in claim 1, wherein said boundary wall of said second sublayer that bounds said third opening is exposed within said third opening, said second metallic electrode has a portion that covers said boundary wall of said second sublayer and that has a width (D3) ranging from 1 μm to 10 μm.

3. The micro LED (100) as claimed in claim 1, wherein:
said second insulating layer is an insulating reflective layer that includes titanium oxide;
said second metallic electrode extends outwardly from inside of said third opening to an outside surface said first insulating layer so as to partially cover said outside surface, a portion of said second metallic electrode that covers said outside surface has a width (D4) ranging from 0.1 μm to 10 μm.

4. The micro LED (100) as claimed in claim 1, wherein:
a boundary wall of said second sublayer that bounds said third opening is exposed within said third opening and has a stepped surface; said stepped surface faces toward an outside of said third opening and is covered by said second metallic electrode; and
said stepped surface of said second sublayer has a height (H1) that ranges from 0.01 μm to 0.2 μm and that is measured from an interface of said first and second sublayers.

5. The micro LED as claimed in claim 1, wherein at least one of said first metallic electrode and said second metallic electrode includes one of chromium, aluminum, titanium, platinum, and gold.

6. The micro LED as claimed in claim 1, wherein a ratio of a thickness of said first insulating layer to a thickness of said first sublayer of said second insulating layer ranges from ¼ to ⅔, or ⅔ to 2.

7. The micro LED as claimed in claim 1, wherein:
said first insulating layer has a thickness ranging from 0.5 μm to 2 μm; and
said first sublayer of said second insulating layer has a thickness ranging from 1 μm to 3 μm.

8. The micro LED as claimed in claim 1, wherein:
said first insulating layer extends from said first mesa to said second mesa via said mesa side wall and forms a contiguous structure with said second sublayer layer of said second insulating layer disposed on said second mesa; and
said first insulating layer includes only one type of dielectric material, and said second insulating layer includes at least two types of dielectric materials.

9. The micro LED as claimed in claim 1, wherein said first insulating layer includes one type of dielectric material and said second insulating layer includes at least two types of dielectric materials.

10. The micro LED as claimed in claim 1, wherein:
said dielectric material of said first insulating layer is silicon oxide or silicon nitride; and
said dielectric materials of said second insulating layer include silicon oxide and silicon nitride, or silicon oxide, silicon nitride, and titanium oxide.

11. The micro LED as claimed in claim 1, wherein:
a boundary wall of said insulating layered unit that bounds said first opening has a first inclined angle (θ1) relative to a surface of said first mesa, a boundary wall of said insulating layered unit that bounds said second opening has a second inclined angle (θ2) relative to a surface of said second mesa that is less than said first inclined angle (θ1);
said first inclined angle (θ1) ranges from 20° to 55°; and said second inclined angle (θ2) ranges from 30° to 60°.

12. The micro LED as claimed in claim 1, wherein:
said second opening is formed on said second mesa, and
a minimum diameter of said second opening is no less than a minimum diameter of said first opening.

13. The micro LED as claimed in claim 1, wherein:
a minimum diameter of said first opening ranges from 1 μm to 3 μm; and
a minimum diameter of said second opening ranges from 1 μm to 5 μm, or 5 μm to 10 μm.

14. The micro LED as claimed in claim 1, wherein:
said semiconductor layered structure has a maximum rectangular cross section that is perpendicular to said thickness direction, said maximum rectangular cross section having a short side (L2) with a length that is no greater than 15 μm, or that ranges from 15 μm to 50 μm; and each lateral side of said first mesa has a length that is no greater than 15 μm, or that ranges from 15 μm to 50 μm.

15. The micro LED as claimed in claim 1, wherein:
said first mesa has a mesa area that is smaller than a mesa area of said second mesa; and
a ratio of said mesa area of said first mesa to said mesa area of said second mesa ranges from ½ to ⅘.

16. The micro LED as claimed in claim 1, wherein:
said first metallic electrode extends to cover said first insulating layer on said second mesa; and
an area of said first metallic electrode covering said second mesa has a width (D2) greater than 20% of, or ranging from 20% to 90% of a length of a short side (L2) of a maximum rectangular cross section of said semiconductor layered structure that is perpendicular to said thickness direction of said semiconductor layered structure.

17. The micro LED as claimed in claim 1, wherein a boundary wall of said insulating layered unit that bounds said second opening has a sloped surface with a varying inclined angle relative to a surface of said second mesa, said varying inclined angle including at least a first angle (θ21) and a second angle (θ22), said second angle (θ22) being more proximate to said third opening than said first angle (θ21), and said second angle (θ22) being smaller than said first angle (θ21).

18. The micro LED as claimed in claim 1, wherein a minimum distance between said first opening and said second opening ranges from 5 μm to 20 μm, or 20 μm to 35 μm.

19. A display device comprising a printed circuit board (PCB) board, and includes a micro LED claimed in claim 1 and mounted on said PCB.
